(19) United States
(12) Patent Application Publication
(10) Pub. No.: US 2023/0033999 A1
(43) Pub. Date: Feb. 2, 2023

(54) THIN FILM TRANSISTOR, FABRICATING METHOD THEREOF AND DISPLAY DEVICE COMPRISING THE SAME

(71) Applicant: LG DISPLAY CO., LTD., SEOUL (KR)

(72) Inventors: Seunghyo KO, Paju-si (KR); Nuri ON, Paju-si (KR); TaeWoong MOON, Paju-si (KR)

(73) Assignee: LG DISPLAY CO., LTD., SEOUL (KR)

(21) Appl. No.: 17/870,065

(22) Filed: Jul. 21, 2022

(30) Foreign Application Priority Data
Jul. 29, 2021 (KR) 10-2021-0099640

(51) Int. Cl. H01L 29/786; H01L 27/32; H01L 29/66

(52) U.S. Cl. CPC H01L 29/7869; H01L 27/3262; H01L 29/66742

(57) ABSTRACT

A thin film transistor for a display device includes an active layer, and a gate electrode spaced apart from the active layer and at least partially overlapping with the active layer, wherein the active layer includes copper, and has a concentration gradient of copper along a thickness direction of the active layer.

### CROSS-REFERENCE TO RELATED APPLICATION

This application claims the priority of Korean Patent Application No. 10-2021-0099640 filed on Jul. 29, 2021, which is hereby incorporated by reference in its entirety.

### BACKGROUND

### Field of the Disclosure

The present disclosure relates to a thin film transistor, a fabricating method thereof, and a display device comprising the same.

### Description of the Background

Since a thin film transistor can be manufactured on a glass substrate or a plastic substrate, the thin film transistor has been widely used as a switching element or a driving element of a display device such as a liquid crystal display device or an organic light emitting device.

The thin film transistor may be categorized into an amorphous silicon thin film transistor in which amorphous silicon is used as an active layer, a polycrystalline silicon thin film transistor in which polycrystalline silicon is used as an active layer and an oxide semiconductor thin film transistor in which oxide semiconductor is used as an active layer, based on a material constituting the active layer.

An oxide semiconductor thin film transistor (TFT), which has a large resistance change in accordance with an oxygen content, has an advantage in that desired properties may be easily obtained. Further, since an oxide constituting an active layer may be grown at a relatively low temperature during a process of fabricating the oxide semiconductor thin film transistor, the fabricating cost of the oxide semiconductor thin film transistor is reduced. In view of the properties of the oxide, since an oxide semiconductor is transparent, it is favorable to embody a transparent display device.

The thin film transistor used as a driving element of the display device is favorable to have a large s-factor to represent a gray scale. Therefore, studies for a thin film transistor used as a driving element of the display device to have a large s-factor are required.

The above information disclosed in this Background section is only for enhancement of understanding of the background of the described technology and therefore it may contain information that does not form prior art that is already known to a person of ordinary skill in the art.

### SUMMARY

Accordingly, the present disclosure is to provide a thin film transistor having a large s-factor as described above.

The present disclosure is also to provide a method of improving an s-factor of a thin film transistor by forming a defect state on a surface of an active layer.

The present disclosure is also to provide a thin film transistor having a large s-factor as the surface of the active layer includes a defect state.

The present disclosure is also to provide a method of forming a defect state on a surface of an active layer by disposing Cu ions on the surface of the active layer and treating the surface of the active layer with heat.

The present disclosure is also to provide a thin film transistor comprising an active layer formed by disposing copper (Cu) ions on the surface and heat-treating the surface of the active layer.

The present disclosure is also to provide a thin film transistor comprising an active layer that includes Cu ions disposed on a surface.

The present disclosure is also to provide a display device comprising a thin film transistor having a large s-factor to achieve an excellent gray scale representation ability.

In addition to the above mentioned, other features of the present disclosure will be clearly understood by those skilled in the art from the following description of the present disclosure.

In accordance with an aspect of the present disclosure, a thin film transistor includes an active layer, and a gate electrode spaced apart from the active layer and at least partially overlapped with the active layer, wherein the active layer includes copper (Cu), and has a concentration gradient of copper along a thickness direction thereof.

A concentration of the copper may be uniform on a surface of the active layer.

The concentrations of the copper may be the same at different points with a same depth from the surface of the active layer.

The active layer may be disposed on a substrate, and the concentration of the copper may be reduced along a direction toward the substrate in the active layer.

The copper (Cu) may include Cu+ and Cu2+.

A concentration of Cu2+ may be higher than that of Cu+ in the active layer.

The concentration of the copper in the active layer may be 0.1 at % (atomic %) to 0.18 at % (atomic %).

The active layer may include an oxide semiconductor material.

The active layer may include a first oxide semiconductor layer, and a second oxide semiconductor layer on the first oxide semiconductor layer.

The active layer may further include a third oxide semiconductor layer on the second oxide semiconductor layer.

The thin film transistor may have an s-factor of 0.2 or more.

In accordance with another aspect of the present disclosure a display device includes the above thin film transistor.

In accordance with another aspect of the present disclosure, a fabricating method of a thin film transistor includes forming an active material layer on a substrate, forming a copper layer on the active material layer, forming an active layer and a copper pattern by patterning the active material layer and the copper layer, removing the copper pattern, and heat-treating the active layer.

After the copper pattern is removed, copper may be present on the surface of the active layer.

The copper pattern may have a thickness of 2 nm to 5 nm.

The heat-treating may be performed at a temperature of 250° C. to 350° C.

The forming an active material layer may include forming a first oxide semiconductor material layer on the substrate, and forming a second oxide semiconductor material layer on the first oxide semiconductor material layer.

The forming an active material layer may further include forming a third oxide semiconductor material layer on the second oxide semiconductor material layer.

### BRIEF DESCRIPTION OF THE DRAWINGS

The above and other features and advantages of the present disclosure will be more clearly understood from the following detailed description taken in conjunction with the accompanying drawings, in which:

FIG. 1 is a cross-sectional view illustrating a thin film transistor according to one aspect of the present disclosure;

FIG. 2 is a schematic cross-sectional view illustrating a surface state of an active layer;

FIG. 3 is a graph illustrating a concentration of ions according to a depth of an active layer;

FIG. 4 is a cross-sectional view illustrating a thin film transistor according to another aspect of the present disclosure;

FIG. 5 is a cross-sectional view illustrating a thin film transistor according to still another aspect of the present disclosure;

FIG. 6 is a cross-sectional view illustrating a thin film transistor according to further still another aspect of the present disclosure;

FIG. 7 is a cross-sectional view illustrating a thin film transistor according to further still another aspect of the present disclosure;

FIG. 8 is a cross-sectional view illustrating a thin film transistor according to further still another aspect of the present disclosure;

FIG. 9 is a graph illustrating threshold voltages of thin film transistors;

FIGS. 10A to 10G are fabricating process views of a thin film transistor according to an aspect of the present disclosure;

FIG. 11A is a graph illustrating activation energy Ea of an active layer;

FIG. 11B is a graph illustrating a density of state (DoS) of an active layer;

FIG. 12 is a schematic view illustrating a display device according to another aspect of the present disclosure;

FIG. 13 is a circuit view illustrating any one pixel of FIG. 12;

FIG. 14 is a plan view illustrating a pixel of FIG. 13;

FIG. 15 is a cross-sectional view taken along line I-I′ of FIG. 14;

FIG. 16 is a circuit view illustrating a pixel of a display device according to still another aspect of the present disclosure;

FIG. 17 is a circuit view illustrating a pixel of a display device according to further still another aspect of the present disclosure; and

FIG. 18 is a circuit view illustrating a pixel of a display device according to further still another aspect of the present disclosure.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing aspects of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜’, ‘above˜’, ‘below˜’, and ‘next to˜’, one or more portions may be arranged between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,”“subsequent,”“next,” and “before,” a case which is not continuous may be included, unless “just” or “direct” is used.

It will be understood that, although the terms “first”, “second”, etc. may be used herein to describe various elements, these elements should not be limited by these terms. These terms are only used to partition one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

In the drawings, the same or similar elements are denoted by the same reference numerals even though they are depicted in different drawings.

In the aspects of the present disclosure, a source electrode and a drain electrode are distinguished from each other, for convenience of description. However, the source electrode and the drain electrode may be used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In some aspects of the present disclosure, for convenience of description, a source region is distinguished from a source electrode, and a drain region is distinguished from a drain electrode. However, the aspects of the present disclosure are not limited to this structure. For example, a source region may be a source electrode, and a drain region may be a drain electrode. Also, a source region may be a drain electrode, and a drain region may be a source electrode.

FIG. 1 is a cross-sectional view illustrating a thin film transistor 100 according to an aspect of the present disclosure.

Referring to FIG. 1, the thin film transistor 100 according to one aspect of the present disclosure includes an active layer 130 and a gate electrode 160. Also, the thin film transistor 100 according to one aspect of the present disclosure includes a source electrode 151 and a drain electrode 152. The active layer 130 and the gate electrode 160 are disposed on a substrate 110.

The substrate 110 may include at least one of glass or polymer resin. For example, a glass substrate or a polymer resin substrate may be used as the substrate 110. There is a plastic substrate as the polymer resin substrate. The plastic substrate may include one of polyimide (PI), polycarbonate (PC), polyethylene (PE), polyester, polyethylene terephthalate (PET) and polystyrene (PS), which are a transparent polymer resin having flexible properties.

Referring to FIG. 1, a light shielding layer 120 may be disposed on the substrate 110. The light shielding layer 120 has a light shielding characteristic. The light shielding layer 120 may shield light incident from the substrate 110 to protect the active layer 130.

The light shielding layer 120 may include metal. The light shielding layer may be made of a single layer, or may have a multi-layered structure.

A buffer layer 125 may be disposed on the light shielding layer 120. The buffer layer 125 covers an upper surface of the light shielding layer 120. The buffer layer 125 has insulation properties and protects the active layer 130. The buffer layer 125 may be referred to as a protective layer or an insulating layer.

The buffer layer 125 may include one of silicon oxide (SiOx), silicon nitride (SiNx), hafnium oxide (HfOx), aluminum oxide (AlOx), zirconium oxide (ZrOx), hafnium silicate (Hf—SiOx), and zirconium silicate (Zr—SiOx), which has insulation properties.

Referring to FIG. 1 the active layer 130 is disposed on the buffer layer 125. The active layer 130 overlaps the light shielding layer 120.

According to one aspect of the present disclosure, the active layer 130 includes an oxide semiconductor material. According to one aspect of the present disclosure, the active layer 130 may be an oxide semiconductor layer made of an oxide semiconductor material, for example.

The active layer 130 may include one of IO (InO)-based, ZO (ZnO)-based, TO (SnO)-based, GO (GaO)-based, IZO (InZnO)-based, IGO (InGaO)-based, IGZO (InGaZnO)-based, IGZTO (InGaZnSnO)-based, GZTO (GaZnSnO)-based, GZO (GaZnO)-based, ITO (InSnO)-based, ITZO (InSnZnO)-based and FIZO (FeInZnO)-based oxide semiconductor material.

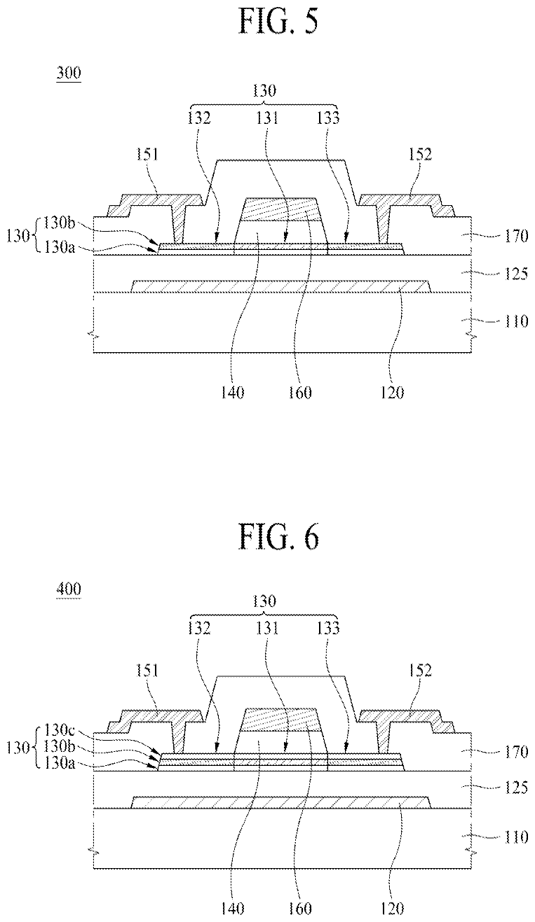

The active layer 130 may have a single layered structure, or may have a multi-layered structure that includes a plurality of oxide semiconductor layers (shown in FIGS. 5 and 6). The active layer 130 may include copper (Cu).

According to an aspect of the present disclosure, copper (Cu) may be present in an ion state. For example, in the active layer 130, the copper (Cu) may be present in a form of Cu₂O or CuO. When copper (Cu) is present in the form of Cu₂O, copper (Cu) may be referred to as a monovalent ion (Cu⁺) state. When copper (Cu) is present in the form of CuO, copper (Cu) may be referred to as a divalent ion (Cu²⁺) state.

In the present disclosure, “copper (Cu)” is meant to include all of copper atoms and copper ions (Cu⁺ and Cu²⁺).

According to the present disclosure, copper (Cu) is primarily disposed on a surface of the active layer 130. In more detail, the copper (Cu) may be primarily disposed on an upper surface of the active layer 130. According to the present disclosure, the upper surface of the active layer 130 is defined as the surface of the active layer 130 opposite to the substrate 110.

The active layer 130 may have a concentration gradient of copper (Cu) along a thickness direction of the active layer 130. In more detail, the concentration of copper (Cu) may vary along the thickness direction of the active layer 130.

The concentration of copper (Cu) on the surface of the active layer 130 may be uniform. The concentrations of copper (Cu) may be the same at different points of the surface of the active layer 130. In addition, the concentration of copper (Cu) may be the same at the same depth from the surface of the active layer 130. The concentrations of the copper (Cu) may be the same at different points with a same depth from a surface of the active layer.

The active layer 130 may be disposed on the substrate 110, and the concentration of copper (Cu) in the active layer 130 may be reduced along a direction toward the substrate 110.

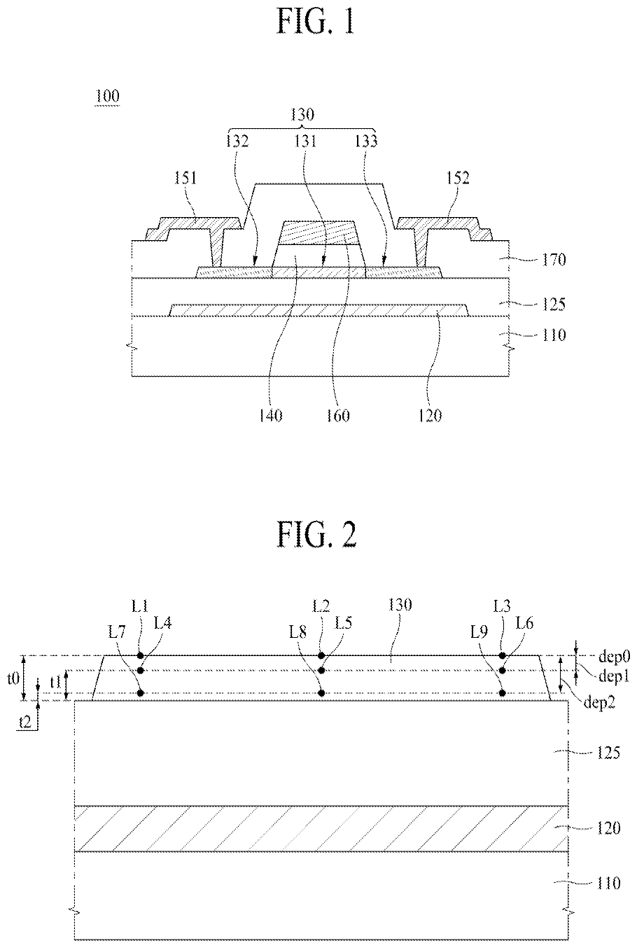

FIG. 2 is a schematic cross-sectional view illustrating a surface state of the active layer 130.

Referring to FIG. 2, the active layer 130 may have a thickness t0. The thickness t0 of the active layer 130 may be defined as a distance between a bottom surface of the active layer 130 and an upper surface of the active layer 130. The bottom surface of the active layer 130 is the same as an upper surface of the buffer layer 125. The upper surface of the active layer 130 is the surface of the active layer 130 opposite to the substrate 110.

According to one aspect of the present disclosure, the depth of the active layer 130 is defined as a distance from the upper surface of the active layer 130 to the direction toward the substrate 110.

L1, L2 and L3 of FIG. 2 correspond to different points on the upper surface of the active layer 130. A height of L1, L2 and L3 is t0, and a depth of L1, L2 and L3 is 0. In FIG. 2, the depth of L1, L2 and L3 is denoted as “dep0”.

The concentrations of copper (Cu) in L1, L2 and L3 that are different points on the upper surface of the active layer 130 are equal to one another.

In FIG. 2, a height of L4, L5 and L6 is t1, and a depth of L4, L5 and L6 is dep1. L4, L5 and L6 are positioned to be deeper than L1, L2 and L3.

The concentrations of copper (Cu) in L4, L5 and L6 may be equal to one another. The concentrations of copper (Cu) in L4, L5 and L6 are lower than the concentrations of copper (Cu) in L1, L2 and L3.

In FIG. 2, a height of L7, L8 and L9 is t2, and a depth of L7, L8 and L9 is dep2. L7, L8 and L9 are positioned to be deeper than L4, L5 and L6.

The concentrations of copper (Cu) in L7, L8 and L9 may be equal to one another. The concentrations of copper (Cu) in L7, L8 and L9 are lower than the concentrations of copper (Cu) in L4, L5 and L6.

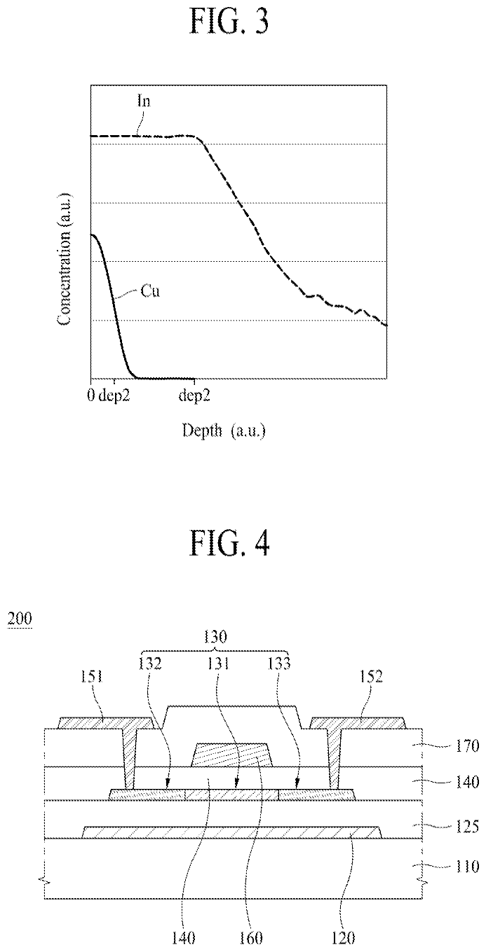

FIG. 3 is a graph illustrating a concentration of ions according to a depth of the active layer 130.

The concentration of ions based on the depth of the active layer 130 may be measured by a depth profile (ToF-SIMS) that uses a Time of Flight Secondary Ion Mass Spectrometry (ToF-SIMS), for example.

According to the present disclosure, the copper (Cu) may have a concentration gradient as shown in FIG. 3 along the thickness direction of the active layer 130. In detail, the copper (Cu) may have a concentration gradient along the thickness direction of the active layer 130 so that the concentration becomes lower as the depth becomes deeper. Alternatively, in the active layer 130, copper (Cu) may have a concentration gradient in such a manner that the concentration is lowered along the direction toward the substrate 110.

Copper (Cu) may not be present at a lower portion of the active layer 130, e.g., the points of L7, L8 and L9.

Copper (Cu) may be present primarily in a divalent ion (Cu²⁺) state. In detail, the copper (Cu) of the active layer 130 includes Cu⁺ and Cu⁺. According to one aspect of the present disclosure, the concentration of Cu⁺ in the active layer 130 may be higher than the concentration of Cu⁺.

After a copper layer is formed on the active layer 130, the copper layer may be removed such that the copper ions (Cu⁺ or CU²⁺) remain on the active layer 130 and then subjected to heat treatment, whereby the copper ions (Cu⁺ or Cu²⁺) may primarily remain in the active layer 130 in the divalent ion (Cu⁺) state. Copper (Cu) may be present in the form of a CuO type copper oxide (i.e., copper (II) oxide) in combination with oxygen in the divalent ion (Cu²⁺) state.

The copper (Cu) combined with oxygen may exhibit an effect such as forming an artificial defect in the active layer 130. The copper (Cu), which causes such defects, may form an acceptor like trap, thereby increasing an s-factor of the thin film transistor 100.

Since copper is contained in the active layer 130 in a small amount, degradation of current characteristics due to copper (Cu) may be minimized. As a result, the s-factor of the thin film transistor 100 may be increased without degradation of the electrical characteristics of the thin film transistor 100.

Also, since copper (Cu) is combined with oxygen to form a stable bond such as CuO, stability of the active layer 130 may be improved, and as a result, stability of the thin film transistor 100 may be improved.

According to one aspect of the present disclosure, the concentration of copper (Cu) in the active layer 130 may be 0.1 atomic % (at %) to 0.18 at %. In this case, the atomic % (at %) may be calculated by a ratio of the number of copper (Cu) atoms to a total number of metal atoms constituting the active layer 130. The total number of metal atoms constituting the active layer 130 does not include the number of oxygen (O) atoms. The atomic % (at %) of each metal constituting the active layer 130 may be calculated by a depth profile (ToF-SIMS depth profile) based on a Time of Flight Secondary Ion Mass Spectrometry (ToF-SIMS).

When the concentration of copper (Cu) in the active layer 130 is less than 0.1 at %, a defect formation and an s-factor increase effect due to copper (Cu) may be rarely exhibited, and stability of the thin film transistor 100 may be slightly improved. On the other hand, when the concentration of Cu in the active layer 130 exceeds 0.18 at %, current characteristics and electrical characteristics of the thin film transistor 100 may be deteriorated.

The active layer 130 may include a channel portion 131, a first connection portion 132 and a second connection portion 133. The first connection portion 132 and the second connection portion 133 may be formed by selective conductorization of the active layer 130. The first connection portion 132 and the second connection portion 133 are generally disposed at both sides of the channel portion 131.

The channel portion 131 has a semiconductor characteristic. The channel portion 131 overlaps the light shielding layer 120. The light shielding layer 120 prevents light incident from the substrate 110 from reaching the channel portion 131 of the active layer 130, thereby protecting the channel portion 131. Also, the channel portion 131 overlaps the gate electrode 160.

A gate insulating layer 140 is disposed on the active layer 130. The gate insulating layer 140 may include at least one of silicon oxide (SiOx), silicon nitride (SiNx), hafnium oxide (HfOx), aluminum oxide (AlOx), zirconium oxide (ZrOx), hafnium silicate (Hf—SiOx) or zirconium silicate (Zr—SiOx). The gate insulating layer 140 may have a single layered structure, or may have a multi-layered structure.

A gate electrode 160 is disposed on the gate insulating layer 140. The gate electrode 160 is spaced apart from the active layer 130, and at least partially overlaps the active layer 130. The gate electrode 160 overlaps the channel portion 131 of the active layer 130.

The gate electrode 160 may include one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), or titanium (Ti). The gate electrode 160 may have a multi-layered structure that includes at least two conductive layers having their respective physical properties different from each other.

An interlayer insulating layer 170 is disposed on the gate electrode 160. The interlayer insulating layer 170 is an insulating layer made of an insulating material. In detail, the interlayer insulating layer 170 may be made of an organic material, may be made of an organic material, or may be made of a stacked body of an organic layer and an inorganic layer.

A source electrode 151 and a drain electrode 152 are disposed on the interlayer insulating layer 170. The source electrode 151 and the drain electrode 152 are spaced apart from each other and connected to the active layer 130, respectively. The source electrode 151 and the drain electrode 152 are respectively connected to the active layer 130 through a contact hole formed in the interlayer insulating layer 170.

Each of the source electrode 151 and the drain electrode 152 may include at least one of molybdenum (Mo), aluminum (Al), chromium (Cr), gold (Au), titanium (Ti), nickel (Ni), neodymium (Nd), copper (Cu) or their alloy. Each of the source electrode 151 and the drain electrode 152 may be made of a single layer made of a metal or a metal alloy, or may be made of two or more layers.

The active layer 130 may be selectively conductorized by selective conductorization using the gate electrode 160 as a mask.

An area of the active layer 130, which is overlapped with the gate electrode 160, is not conductorized, and thus becomes the channel portion 131. An area of the active layer 130, which is not overlapped with the gate electrode 160, is conductorized and thus becomes the first connection portion 132 and the second connection portion 133.

The active layer 130 may be selectively conductorized by, for example, a plasma treatment or a dry etch, but one aspect of the present disclosure is not limited thereto. The active layer 130 may be selectively conductorized by doping using a dopant. At this time, the doped area is conductorized. For doping, doping may be performed by at least one of, for example, boron (B) ions, phosphorus (P) ions, arsenic (As) ions or antimony (Sb) ions. In addition, the active layer 130 may be selectively conductorized by light irradiation.

Any one of the first connection portion 132 and the second connection portion 133 may be a source area, and the other one thereof may be a drain area. The source area may serve as a source connection portion connected with the source electrode 151. The drain area may serve as a drain connection portion connected with the drain electrode 152.

The first connection portion 132 and the second connection portion 133, which are shown in the drawings, are distinguished from each other for convenience of description, and the first connection portion 132 and the second connection portion 133 may be used interchangeably. The first connection portion 132 may be a source area, and the second connection portion 133 may be a drain area. In addition, the first connection portion 132 may be a drain area, and the second connection portion 133 may be a source area.

The first connection portion 132 may serve as a source electrode, or may serve as a drain electrode. In addition, the second connection portion 133 may serve as a drain electrode, or may serve as a source electrode.

A thin film transistor TFT is formed by the active layer 130, the gate electrode 160, the source electrode 151 and the drain electrode 152. As shown in FIG. 1, a thin film transistor in which the gate electrode 160 is disposed above the active layer 130 may be referred to as a thin film transistor TFT of a top gate structure.

As a trace amount of copper (Cu) is mainly present on the surface of the active layer 130 in a divalent ion (Cu²⁺) state, the s-factor of the thin film transistor 100 can be increased and stability of the thin film transistor 100 can be improved without deterioration of electrical characteristics and reliability.

FIG. 4 is a cross-sectional view illustrating a thin film transistor 200 according to another aspect of the present disclosure.

Referring to FIG. 4, the gate insulating layer 140 is not patterned, and may fully cover the upper surface of the active layer 130. The gate insulating layer 140 may fully cover the upper portion of the substrate 110 except for a contact hole area.

When the gate insulating layer 140 is not patterned and fully covers the upper surface of the active layer 130, the active layer 130 may be selectively conductorized by doping using a dopant. As a result, even though the gate insulating layer 140 is not patterned, the first connection portion 132 and the second connection portion 133 of the active layer 130 may be formed.

FIG. 5 is a cross-sectional view illustrating a thin film transistor 200 according to still another aspect of the present disclosure.

Referring to FIG. 5, the active layer 130 includes a first oxide semiconductor layer 130a, and a second oxide semiconductor layer 130b on the first oxide semiconductor layer 130a.

The first oxide semiconductor layer 130a is disposed on the buffer layer 125, and may serve as a support layer for supporting the second oxide semiconductor layer 130b. The second oxide semiconductor layer 130b may serve as a main channel layer.

The first oxide semiconductor layer 130a serving as a support layer may have excellent film stability and mechanical stability. The first oxide semiconductor layer 130a may include at least one of, for example, IGZO (InGaZnO)-based, IGO (InGaO)-based, IGZTO (InGaZnSnO)-based, GZTO (GaZnSnO)-based, GZO (GaZnO)-based or GO (GaO)-based oxide semiconductor material, but one aspect of the present disclosure is not limited thereto. The first oxide semiconductor layer 130a may be made of another oxide semiconductor material known in the art.

The second oxide semiconductor layer 130b may be made of an oxide semiconductor material such as IZO (InZnO)-based, TO (SnO)-based, IO (InO)-based, IGO (InGaO)-based, ITO (InSnO)-based, IGZO (InGaZnO)-based, IGZTO (InGaZnSnO)-based, GZTO (GaZnSnO)-based, ITZO (InSnZnO)-based, and FIZO (FeInZnO)-based oxide semiconductor material. For example, the second oxide semiconductor layer 132 may include FIZO (FeInZnO)-based oxide semiconductor material. However, the present disclosure is not limited to this example, and the second oxide semiconductor layer 132 may be made of another oxide semiconductor materials known in the art.

FIG. 6 is a cross-sectional view illustrating a thin film transistor 400 according to further still another aspect of the present disclosure.

The thin film transistor 400 shown in FIG. 6 further includes a third oxide semiconductor layer 130c on the second oxide semiconductor layer 130b as compared with the thin film transistor 300 shown in FIG. 5. The third oxide semiconductor layer 130c may be made of an oxide semiconductor material. The third oxide semiconductor layer 130c may be made of the same material as that of the first oxide semiconductor layer 130a.

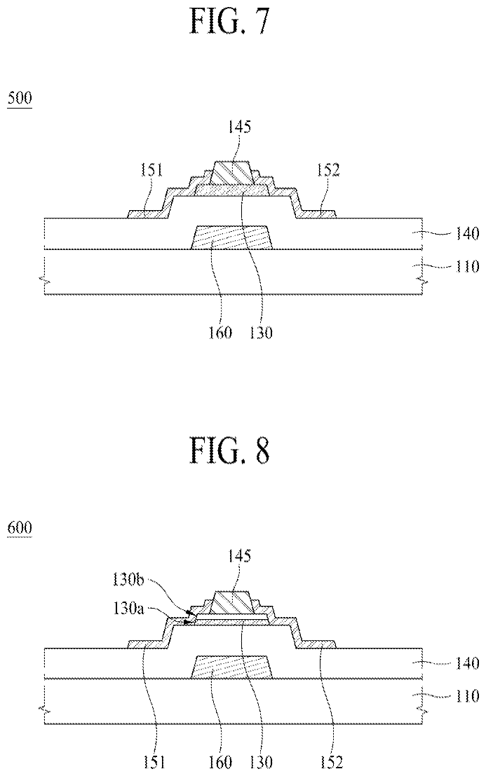

FIG. 7 is a cross-sectional view illustrating a thin film transistor 500 according to further still another aspect of the present disclosure.

The thin film transistor 500 of FIG. 7 includes a gate electrode 160 on the substrate 110, a gate insulating layer 140 on the gate electrode 160, an active layer 130 on the gate insulating layer 140, a source electrode 151 connected to the active layer 130, and a drain electrode 152 spaced apart from the source electrode 151 and connected to the active layer 130. Referring to FIG. 7, the thin film transistor 500 may further include an etch stopper 145.

The active layer 130 may include an oxide semiconductor material.

Referring to FIG. 7, the gate electrode 160 is disposed between the substrate 110 and the active layer 130. As shown in FIG. 7, a structure in which the gate electrode 160 is disposed below the active layer 130 is referred to as a bottom gate structure. The active layer 130 may include copper (Cu). Since the copper (Cu) included in the active layer 130 has been already described, its detailed description will be omitted to avoid redundancy.

FIG. 8 is a cross-sectional view illustrating a thin film transistor 600 according to further still another aspect of the present disclosure.

As shown in FIG. 8, the active layer 130 may include a first oxide semiconductor layer 130a and a second oxide semiconductor layer 130b on the first oxide semiconductor layer 130a, but further still another aspect of the present disclosure is not limited thereto. The active layer 130 may further include a third oxide semiconductor layer 130c disposed on the second oxide semiconductor layer 130b.

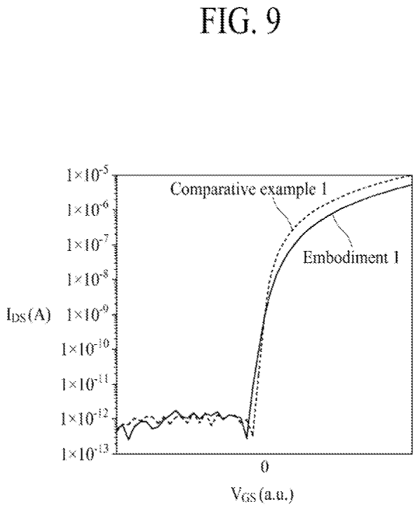

Hereinafter, an s-factor will be described with reference to FIG. 9.

FIG. 9 is a graph illustrating threshold voltages of thin film transistors.

In FIG. 9, “Aspect 1” refers to a threshold voltage graph of a thin film transistor according to one aspect of the present disclosure, which has an active layer 130 containing copper (Cu). In FIG. 9, “Comparative Example 1” refers to a threshold voltage graph of a thin film transistor having an active layer 130 that does not contain copper (Cu).

The threshold voltage graph of FIG. 9 is indicated by a value of a drain-source current I_{DS} for a gate voltage V_{GS} of the thin film transistor.

In a drain-source current I_{DS} graph for a gate voltage V_{GS} of the thin film transistor, the s-factor (sub-threshold swing) is obtained by an inverse value of a slope of the graph at a period of a threshold voltage Vth. For example, at the period of the threshold voltage Vth or V0 of the thin film transistor, the s-factor may be used as an index indicating a change level of the drain-source current for the gate voltage.

When the s-factor becomes large, a change rate of the drain-source current I_{DS} for the gate voltage at the period of the threshold voltage Vth becomes slow.

FIG. 9 illustrates the drain-source current I_{DS} for the gate voltage V_{GS}. At the period of the threshold voltage Vth of the graphs shown in FIG. 9, an inverse number in the graph of the drain-source current I_{DS} for the gate voltage V_{GS} is the s-factor. When the s-factor is large, a change rate of the drain-source current I_{DS} for the gate voltage at the period of the threshold voltage Vth is slow.

When the s-factor becomes large, since the change rate of the drain-source current I_{DS} for the gate voltage at the period of the threshold voltage Vth becomes slow, it is easy to adjust the magnitude of the drain-source current I_{DS} by adjusting the gate voltage V_{GS}.

In the display device driven by the current, for example, in an organic light emitting display device, a gray scale of a pixel may be controlled by adjusting the magnitude of the drain-source current I_{DS} of the driving thin film transistor. The magnitude of the drain-source current I_{DS} of the driving thin film transistor is determined by the gate voltage. Therefore, in the organic light emitting display device driven by the current, it is easy to adjust the gray scale of the pixel by adjusting the gate voltage as the s-factor of the driving TFT becomes large.

Referring to FIG. 9, it may be noted that the slope of the threshold voltage graph of the thin film transistor according to Comparative Example 1 is greater than the threshold voltage graph of the thin film transistor according to Aspect 1 in the vicinity of the threshold voltage 0V.

In the vicinity of the threshold voltage 0V, the change rate of the drain-source current I_{DS} of the thin film transistor according to Aspect 1 is smaller than the change rate of the drain-source current I_{DS} of the thin film transistor according to Comparative Example 1. Referring to FIG. 9, the thin film transistor 100 according to one aspect of the present disclosure may have an s-factor of 0.2 or more. When the thin film transistor 100 according to one aspect of the present disclosure, which has an s-factor of 0.2 or more, is used, the gray level of the display device may be easily adjusted.

In detail, when the thin film transistor 100 according to one aspect of the present disclosure like Aspect 1 is applied to the display device, the magnitude of the drain-source current I_{DS} may be easily adjusted by adjusting the gate voltage, and as a result, the gray scale of the pixel may be easily adjusted.

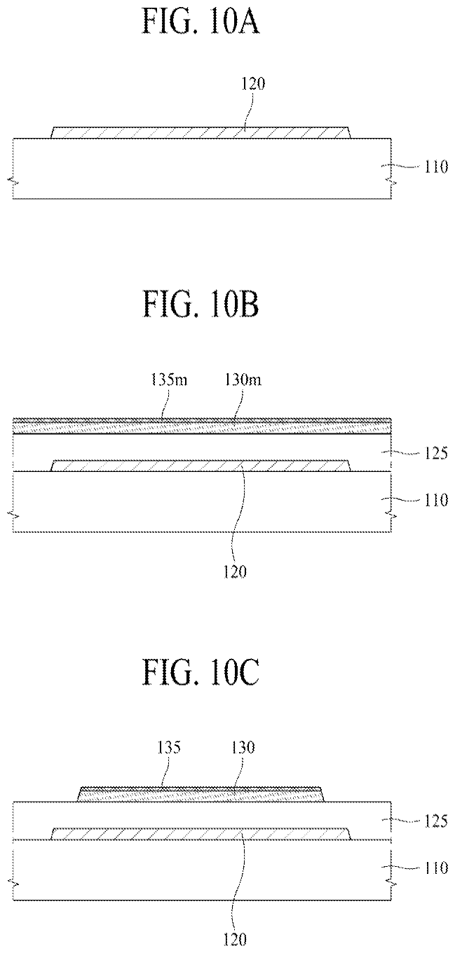

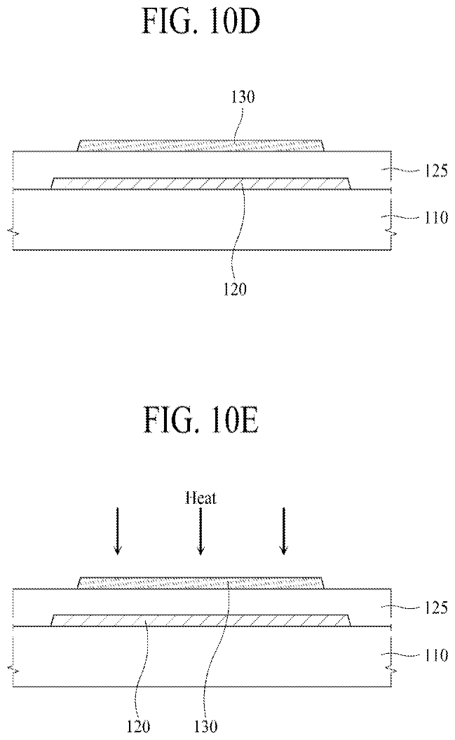

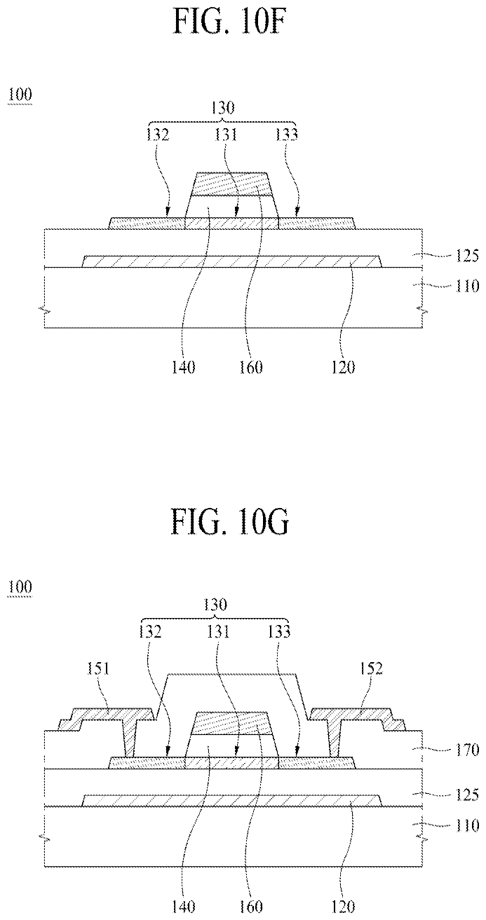

Hereinafter, a fabricating method of the thin film transistor 100 according to one aspect of the present disclosure will be described with reference to FIGS. 10A to 10G.

FIGS. 10A to 10G are fabricating process views of a thin film transistor according to one aspect of the present disclosure.

Referring to FIG. 10A, a light shielding layer 120 is formed on a substrate 110.

Referring to FIG. 10B, a buffer layer 125 is formed on the light shielding layer 120, and an active material layer 130m is formed on the buffer layer 125. Also, a copper layer 135m is formed on the active material layer 130m.

The active material layer 130m may include an oxide semiconductor material. The active material layer 130m may be formed of an oxide semiconductor material. The active material layer 130m may be made of a single layer, or may have a multi-layered structure.

For example, the step of forming the active material layer 130m may include forming a first oxide semiconductor material layer on the substrate 110 and forming a second oxide semiconductor material layer on the first oxide semiconductor material layer. The step of forming the active material layer 130m may further include forming a third oxide semiconductor material layer on the second oxide semiconductor material layer.

The copper layer 135m includes copper (Cu). The copper layer 135m may be made by copper (Cu).

Referring to FIG. 10C, the active material layer 130m and the copper layer 135m are patterned to form an active layer 130 and a copper pattern 135. According to one aspect of the present disclosure, the copper pattern 135 may have a thickness of 2 nm to 5 nm. When the thickness of the copper pattern 135 is less than 2 nm, the amount of copper (Cu) remaining in the active layer 130 after removal of the copper pattern 135 may be too small. On the other hand, when the thickness of the copper pattern 135 exceeds 5 nm, it is not easy to remove the copper pattern 135, or much time may be required to remove the copper pattern 135.

Referring to FIG. 10D, the copper pattern 135 is removed. As a result, the surface of the active layer 130 is exposed. The copper pattern 135 may be removed by, for example, a wet etch.

According to one aspect of the present disclosure, after the copper pattern 135 is removed, copper is present on the surface of the active layer 130. Even though the copper pattern 135 is removed, copper (Cu) is not completely removed. For example, on a boundary surface between the active material layer 130m and the copper layer 135m, coppers(Cu) that have been combined with the materials constituting the active material layer 130m may remain without being removed.

Referring to FIG. 10E, the active layer 130 is heat-treated. A monovalent ion (Cu⁺) state may be oxidized to a divalent ion (Cu²⁺) state by heat treatment. For example, in the active layer 130, copper (Cu) may be present in a combined state with oxygen (O), and the combined state of the copper (Cu) and the oxygen (O) may be changed from a Cu₂O state to a CuO state by heat treatment. As a result, copper (Cu) may form an artificial defect in the active layer 130. Copper (Cu) causing such a defect may form an acceptor like trap to increase the s-factor of the thin film transistor 100.

According to one aspect of the present disclosure, a heat treatment temperature of the active layer 130 may range from 250° C. to 350° C. When the heat treatment temperature is less than 250° C., the degree of Cu₂O changed to CuO is not sufficient, whereby the defect in the active layer 130 is not sufficient. For this reason, since the acceptor trap effect is not sufficient, the s-factor of the thin film transistor 100 may not be increased within a great range. On the other hand, when the heat treatment temperature exceeds 350° C., the active layer 130 may be damaged by the high temperature.

Referring to FIG. 10F, a gate insulating layer 140 may be formed on the active layer 130, and a gate electrode 160 may be formed on the gate insulating layer 140.

In addition, the active layer 130 may be selectively conductorized by selective conductorization using the gate electrode 160 as a mask. As a result, an area of the active layer 130, which is overlapped with the gate electrode 160, is not conductorized and thus may become the channel portion 131, and an area of the active layer 130, which is not overlapped with the gate electrode 160, is conductorized and thus may become the first connection portion 132 and the second connection portion 133.

Referring to FIG. 10G, an interlayer insulating layer 170 may be formed on the gate electrode 160, and a source electrode 151 and a drain electrode 152 may be formed on the interlayer insulating layer 170. As a result, a thin film transistor 100 according to one aspect of the present disclosure may be made.

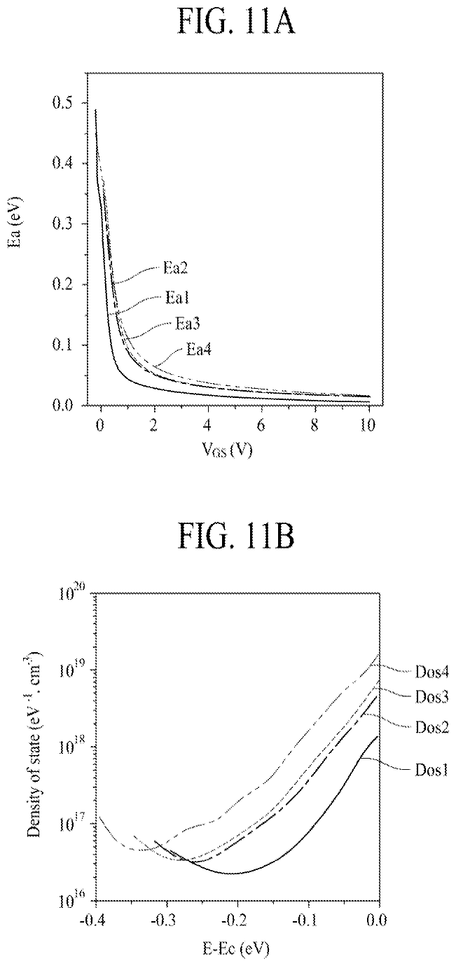

FIG. 11A is a graph illustrating activation energy Ea of the active layer 130. According to one aspect of the present disclosure, the graph of the activation energy Ea may be represented by the activation energy Ea for the gate voltage V_{GS}.

In FIG. 11A, “Ea1” represents the activation energy Ea of the active layer 130 that does not contain copper (Cu), “Ea2” represents the activation energy Ea of the active layer 130 when the heat treatment temperature is 150° C. at the heat-treating step for the active layer 130 shown in FIG. 10E during the fabricating step of the thin film transistor 100, “Ea3” represents the activation energy Ea of the active layer 130 when the heat treatment temperature is 230° C. at the heat-treating step for the active layer 130 shown in FIG. 10E during the fabricating step of the thin film transistor 100, and “Ea4” represents the activation energy Ea of the active layer 130 when the heat treatment temperature is 300° C. at the heat-treating step for the active layer 130 shown in FIG. 10E during the fabricating step of the thin film transistor 100.

Referring to FIG. 11A, it is noted that a large amount of energy is required to activate an element of the active layer 130 when the heat treatment temperature is 300° C. Therefore, it is noted that stability of the active layer 130 is improved when the active layer 130 is heat-treated at 300° C.

Also, according to one aspect of the present disclosure, as the heat treatment temperature for the active layer 130 containing copper (Cu) is increased, a positive bias voltage stress (PBTS) and hysteresis are reduced, whereby it is noted that stability of the thin film transistor 100 and the active layer 130 is improved.

FIG. 11B is a graph illustrating a density of state (DOS) of the active layer 130. According to one aspect of the present disclosure, the Density of State (DOS) graph is indicated by the number of states per unit volume and per unit energy.

In FIG. 11B, “Dos1” represents the density of state (DOS) of the active layer 130 that does not contain copper (Cu), “Dos2” represents the density of state (DOS) of the active layer 130 when the heat treatment temperature is 150° C. at the heat-treating step for the active layer 130 shown in FIG. 10E during the fabricating step of the thin film transistor 100, “Dos3” represents the density of state (DOS) of the active layer 130 when the heat treatment temperature is 230° C. at the heat-treating step for the active layer 130 shown in FIG. 10E during the fabricating step of the thin film transistor 100, and “Dos4” represents the density of state (DOS) of the active layer 130 when the heat treatment temperature is 300° C. at the heat-treating step for the active layer 130 shown in FIG. 10E during the fabricating step of the thin film transistor 100.

Referring to FIG. 11B, it is noted that the density of state (DOS) of the active layer 130 is the highest when the heat treatment temperature is 300° C. Therefore, when the active layer 130 is heat-treated at 300° C., since the density of state (DOS) of the active layer 130 is high, an artificial defect of the active layer 130 is formed, whereby an acceptor trap effect is generated. As a result, it is noted that the s-factor of the thin film transistor 100 is increased.

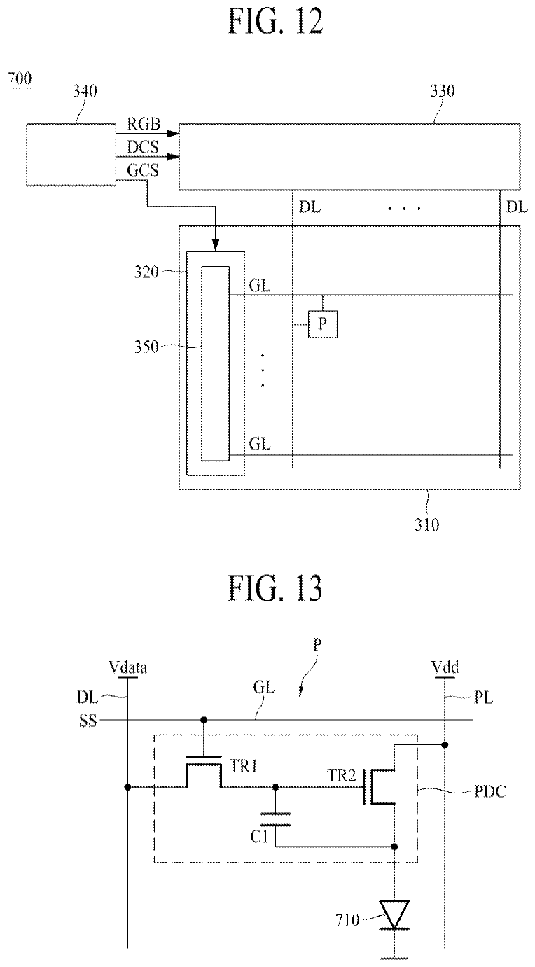

FIG. 12 is a schematic view illustrating a display device 700 according to further still another aspect of the present disclosure.

As shown in FIG. 12, the display device 700 includes a display panel 310, a gate driver 320, a data driver 330 and a controller 340.

Gate lines GL and data lines DL are disposed in the display panel 310, and pixels P are disposed in intersection areas of the gate lines GL and the data lines DL. An image is displayed by driving of the pixels P.

The controller 340 controls the gate driver 320 and the data driver 330.

The controller 340 outputs a gate control signal GCS for controlling the gate driver 320 and a data control signal DCS for controlling the data driver 330 by using a signal that is supplied from an external system (not shown). Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

The gate driver 320 may include a shift register 350.

The shift register 350 sequentially supplies gate pulses to the gate lines GL for one frame by using the start signal and the gate clock, which are transmitted from the controller 340. In this case, one frame means a time period when one image is output through the display panel 310. The gate pulse has a turn-on voltage that may turn on a switching element (thin film transistor) disposed in the pixel P.

Also, the shift register 350 supplies a gate-off signal capable of turning off a switching element, to the gate line GL for the other period of one frame, at which the gate pulse is not supplied. Hereinafter, the gate pulse and the gate-off signal will collectively be referred to as a scan signal SS or Scan.

According to one aspect of the present disclosure, the gate driver 320 may be packaged on the substrate 110. In this way, a structure in which the gate driver 320 is directly packaged on the substrate 110 will be referred to as a Gate In Panel (GIP) structure.

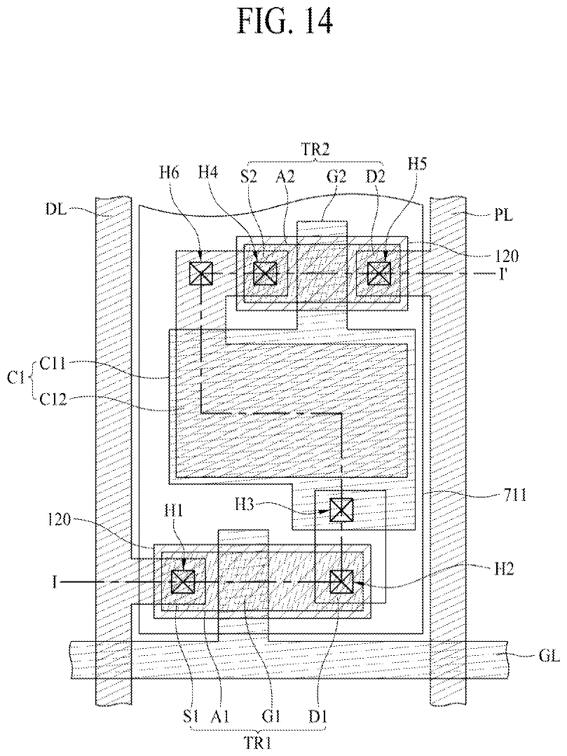

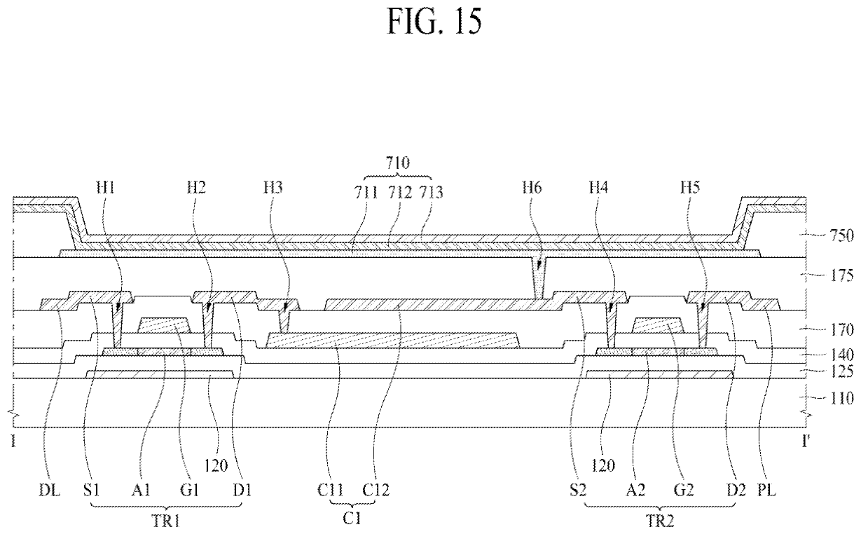

FIG. 13 is a circuit view illustrating any one pixel P of FIG. 12, FIG. 14 is a plan view illustrating a pixel P of FIG. 13, and FIG. 15 is a cross-sectional view taken along line I-I′ of FIG. 14.

The circuit view of FIG. 13 is an equivalent circuit view for the pixel P of the display device 600 that includes an organic light emitting diode (OLED) as a display element 710.

The pixel P includes a display element 710 and a pixel driving circuit PDC for driving the display element 710.

The pixel driving circuit PDC of FIG. 13 includes a first thin film transistor TR1 that is a switching transistor, and a second thin film transistor TR2 that is a driving transistor.

The display device 700 according to further still another aspect of the present disclosure may include at least one of the thin film transistors 100, 200, 300, 400, 500 and 600 shown in FIGS. 1 and 4 to 8. At least one of the thin film transistors 100, 200, 300, 400, 500 and 600 shown in FIGS. 1 and 4 to 8 may be used as the second thin film transistor TR2 that is a driving transistor.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

A driving power line PL provides a driving voltage Vdd to the display element 710, and the second thin film transistor TR2 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode G2 of the second thin film transistor TR2 connected with the display element 710. The data voltage Vdata is charged in a first capacitor C1 formed between the gate electrode G2 and a source electrode S2 of the second thin film transistor TR2. The first capacitor C1 is a storage capacitor Cst.

The amount of a current supplied to the organic light emitting diode (OLED), which is the display element 710, through the second thin film transistor TR2 is controlled in accordance with the data voltage Vdata, whereby a gray scale of light emitted from the display element 710 may be controlled.

Referring to FIGS. 14 and 15, the first thin film transistor TR1 and the second thin film transistor TR2 are disposed on the substrate 110.

The substrate 110 may be made of glass or plastic. Plastic having a flexible property, for example, polyimide (PI) may be used as the substrate 110.

A light shielding layer 120 is disposed on the substrate 110. The light shielding layer 120 may shield light incident from the outside to protect active layers A1 and A2.

A buffer layer 125 is disposed on the light shielding layer 120. The buffer layer 125 is made of an insulating material, and protects the active layers A1 and A2 from external water or oxygen.

The active layer A1 of the first thin film transistor TR1 and the active layer A2 of the second thin film transistor TR2 are disposed on the buffer layer 125.

Each of the active layers A1 and A2 may include an oxide semiconductor material. According to another aspect of the present disclosure, the active layers A1 and A2 are oxide semiconductor layers made of an oxide semiconductor material.

A gate insulating layer 140 is disposed on the active layers A1 and A2. The gate insulating layer 140 has insulation properties, and spaces the active layers A1 and A2 apart from the gate electrodes G1 and G2. The gate insulating layer 140 that is not patterned is shown in FIG. 15, but another aspect of the present disclosure is not limited thereto. The gate insulating layer 140 may be patterned as shown in FIG. 1.

The gate electrode G1 of the first thin film transistor TR1 and the gate electrode G2 of the second thin film transistor TR2 are disposed on the gate insulating layer 140.

The gate electrode G1 of the first thin film transistor TR1 overlaps at least a portion of the active layer A1 of the first thin film transistor TR1.

The gate electrode G2 of the second thin film transistor TR2 overlaps at least a portion of the active layer A2 of the second thin film transistor TR2.

Referring to FIGS. 14 and 15, a first capacitor electrode C11 of the first capacitor C1 is disposed in the same layer as the gate electrodes G1 and G2. The gate electrodes G1 and G2 and the first capacitor electrode C11 may be made together by the same process using the same material.

An interlayer insulating layer 170 is disposed on the gate electrodes G1 and G2 and the first capacitor electrode C11.

The source electrodes S1 and S2 and the drain electrodes D1 and D2 are disposed on the interlayer insulating layer 170. According to one aspect of the present disclosure, the source electrodes S1 and S2 and the drain electrodes D1 and D2 are distinguished for convenience of description, and the source electrodes S1 and S2 and the drain electrodes D1 and D2 may be used interchangeably. Therefore, the source electrodes S1 and S2 may be the drain electrodes D1 and D2, and the drain electrodes D1 and D2 may be the source electrodes S1 and S2.

A data line DL and a driving power line PL are disposed on the interlayer insulating layer 170. The source electrode S1 of the first thin film transistor TR1 may be integrally formed with the data line DL. The drain electrode D2 of the second thin film transistor TR2 may be integrally formed with the driving power line PL.

According to one aspect of the present disclosure, the source electrode S1 and the drain electrode D1 of the first thin film transistor TR1 are spaced apart from each other and connected with the active layer A1 of the first thin film transistor TR1. The source electrode S2 and the drain electrode D2 of the second thin film transistor TR2 are spaced apart from each other and connected with the active layer A2 of the second thin film transistor TR2.

In detail, the source electrode S1 of the first thin film transistor TR1 is in contact with a source area of the active layer A1 through a first contact hole H1.

The drain electrode D1 of the first thin film transistor TR1 is in contact with a drain area of the active layer A1 through a second contact hole H2, and is connected with the first capacitor electrode C11 of the first capacitor C1 through a third contact hole H3.

The source electrode S2 of the second thin film transistor TR2 is extended over the interlayer insulating layer 170, and thus a portion thereof serves as a second capacitor electrode C12 of the first capacitor C1. The first capacitor electrode C11 and the second capacitor electrode C12 are overlapped with each other to form the first capacitor C1.

The source electrode S2 of the second thin film transistor TR2 is in contact with the source area of the active layer A2 through a fourth contact hole H4.

The drain electrode D2 of the second thin film transistor TR2 is in contact with the drain area of the active layer A2 through a fifth contact hole H5.

The first thin film transistor TR1 includes an active layer A1, a gate electrode G1, a source electrode S1 and a drain electrode D1, and serves as a switching transistor for controlling the data voltage Vdata applied to the pixel driving circuit PDC.

The second thin film transistor TR2 includes an active layer A2, a gate electrode G2, a source electrode S2 and a drain electrode D2, and serves as a driving transistor for controlling the driving voltage Vdd applied to the display element 710.

A passivation layer 175 is disposed on the source electrodes S1 and S2, the drain electrodes D1 and D2, the data line DL and the driving power line PL. The passivation layer 175 planarizes upper portions of the first thin film transistor TR1 and the second thin film transistor TR2 and protects the first thin film transistor TR1 and the second thin film transistor TR2.

A first electrode 711 of the display element 710 is disposed on the passivation layer 175. The first electrode 711 of the display element 710 is connected with the source electrode S2 of the second thin film transistor TR2 through a sixth contact hole H6 formed in the passivation layer 175.

A bank layer 750 is disposed at an edge of the first electrode 711. The bank layer 750 defines a light emission area of the display element 710.

An organic light emitting layer 712 is disposed on the first electrode 711, and a second electrode 713 is disposed on the organic light emitting layer 712. Therefore, the display element 710 is completed. The display element 710 shown in FIG. 15 is an organic light emitting diode (OLED). Therefore, the display device 100 according to another aspect of the present disclosure is an organic light emitting display device.

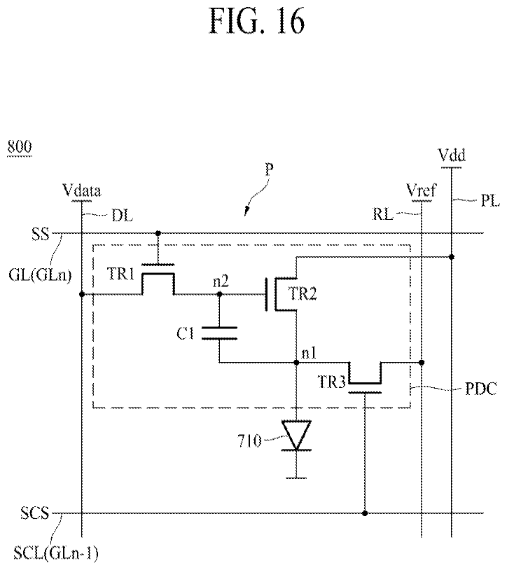

FIG. 16 is a circuit view illustrating a pixel P of a display device 800 according to further still another aspect of the present disclosure.

FIG. 16 is an equivalent circuit view illustrating a pixel P of an organic light emitting display device.

The pixel P of the display device 800 shown in FIG. 16 includes an organic light emitting diode (OLED) that is a display element 710 and a pixel driving circuit PDC for driving the display element 710. The display element 710 is connected with the pixel driving circuit PDC.

In the pixel P, signal lines DL, GL, PL, RL and SCL for supplying a signal to the pixel driving circuit PDC are disposed.

The data voltage Vdata is supplied to the data line DL, the scan signal SS is supplied to the gate line GL, the driving voltage Vdd for driving the pixel is supplied to the driving power line PL, a reference voltage Vref is supplied to a reference line RL, and a sensing control signal SCS is supplied to a sensing control line SCL.

Referring to FIG. 16, assuming that a gate line of an (n)th pixel P is “GLₙ”, a gate line of a (n-1)th pixel P adjacent to the (n)th pixel P is “GLₙ₋₁” and the gate line “GLₙ₋₁” of the (n-1)th pixel P serves as a sensing control line SCL of the (n)th pixel P.

The pixel driving circuit PDC includes, for example, a first thin film transistor TR1 (switching transistor) connected with the gate line GL and the data line DL, a second thin film transistor TR2 (driving transistor) for controlling a magnitude of a current output to the display element 710 in accordance with the data voltage Vdata transmitted through the first thin film transistor TR1, and a third thin film transistor TR3 (reference transistor) for sensing characteristics of the second thin film transistor TR2.

A first capacitor C1 is disposed between a gate electrode G2 of the second thin film transistor TR2 and the display element 710. The first capacitor C1 is referred to as a storage capacitor Cst.

The first thin film transistor TR1 is turned on by the scan signal SS supplied to the gate line GL to transmit the data voltage Vdata, which is supplied to the data line DL, to the gate electrode G2 of the second thin film transistor TR2.

The third thin film transistor TR3 is connected to a first node n1 between the second thin film transistor TR2 and the display element 710 and the reference line RL, and thus is turned on or off by the sensing control signal SCS and senses characteristics of the second thin film transistor TR2, which is a driving transistor, for a sensing period.

A second node n2 connected with the gate electrode G2 of the second thin film transistor TR2 is connected with the first thin film transistor TR1. The first capacitor C1 is formed between the second node n2 and the first node n1.

When the first thin film transistor TR1 is turned on, the data voltage Vdata supplied through the data line DL is supplied to the gate electrode G2 of the second thin film transistor TR2. The data voltage Vdata is charged in the first capacitor C1 formed between the gate electrode G2 and the source electrode S2 of the second thin film transistor TR2.

When the second thin film transistor TR2 is turned on, the current is supplied to the display element 710 through the second thin film transistor TR2 in accordance with the driving voltage Vdd for driving the pixel, whereby light is output from the display element 710.

The display device 800 according to further still another aspect of the present disclosure may include at least one of the thin film transistors 100, 200, 300, 400, 500 and 600 shown in FIGS. 1 and 4 to 8. Any one of the thin film transistors 100, 200, 300, 400, 500 and 600 shown in FIGS. 1 and 4 to 8 may be used as the second thin film transistor TR2.

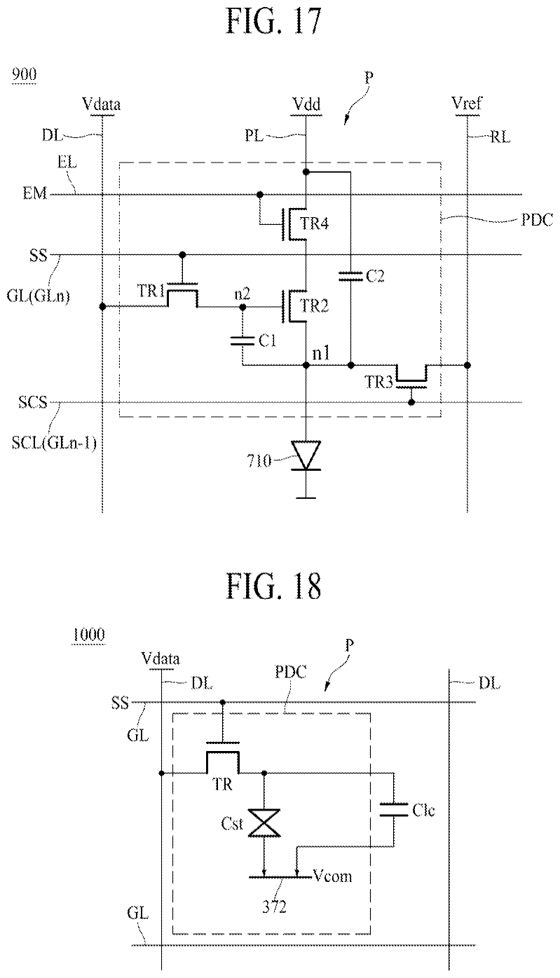

FIG. 17 is a circuit view illustrating a pixel of a display device 900 according to further still another aspect of the present disclosure.

The pixel P of the display device 900 shown in FIG. 17 includes an organic light emitting diode (OLED) that is a display element 710 and a pixel driving circuit PDC for driving the display element 710. The display element 710 is connected with the pixel driving circuit PDC.

The pixel driving circuit PDC includes thin film transistors TR1, TR2, TR3 and TR4.

In the pixel P, signal lines DL, EL, GL, PL, SCL and RL for supplying a driving signal to the pixel driving circuit PDC are disposed.

In comparison with the pixel P of FIG. 16, the pixel P of FIG. 17 further includes an emission control line EL. An emission control signal EM is supplied to the emission control line EL.

Also, the pixel driving circuit PDC of FIG. 17 further includes a fourth thin film transistor TR4 that is an emission control transistor for controlling a light emission timing of the second thin film transistor TR2, in comparison with the pixel driving circuit PDC of FIG. 16.

Referring to FIG. 17, assuming that a gate line of an (n)th pixel P is “GLₙ”, a gate line of a (n-1)th pixel P adjacent to the (n)th pixel P is “GLₙ₋₁”, and the gate line “GLₙ₋₁” of the (n-1)th pixel P serves as a sensing control line SCL of the (n)th pixel P.

A first capacitor C1 is positioned between the gate electrode G2 of the second thin film transistor TR2 and the display element 710. A second capacitor C2 is positioned between one of terminals of the fourth thin film transistor TR4, to which a driving voltage Vdd is supplied, and one electrode of the display element 710.

The first thin film transistor TR1 is turned on by the scan signal SS supplied to the gate line GL to transmit the data voltage Vdata, which is supplied to the data line DL, to the gate electrode G2 of the second thin film transistor TR2.

The third thin film transistor TR3 is connected to the reference line RL and thus turned on or off by the sensing control signal SCS, and senses characteristics of the second thin film transistor TR2, which is a driving transistor, for a sensing period.

The fourth thin film transistor TR4 transfers the driving voltage Vdd to the second thin film transistor TR2 in accordance with the emission control signal EM or shields the driving voltage Vdd. When the fourth thin film transistor TR4 is turned on, a current is supplied to the second thin film transistor TR2, whereby light is output from the display element 710.

The display device 900 according to further still another aspect of the present disclosure may include at least one of the thin film transistors 100, 200, 300, 400, 500 and 600 shown in FIGS. 1 and 4 to 8.

The pixel driving circuit PDC according to further still another aspect of the present disclosure may be formed in various structures in addition to the above-described structure. The pixel driving circuit PDC may include, for example, five or more thin film transistors.

FIG. 18 is a circuit view illustrating a pixel P of a display device 1000 according to further still another aspect of the present disclosure.

The display device 1000 of FIG. 18 is a liquid crystal display device.

The pixel P of the display device 1000 shown in FIG. 18 includes a pixel driving circuit PDC and a liquid crystal capacitor Clc connected with the pixel driving circuit PDC. The liquid crystal capacitor Clc corresponds to the display element.

The pixel driving circuit PDC includes a thin film transistor TR connected with the gate line GL and the data line DL, and a storage capacitor Cst connected between the thin film transistor TR and a common electrode 372. The liquid crystal capacitor Clc is connected with the storage capacitor Cst in parallel between the thin film transistor TR and the common electrode 372.

The liquid crystal capacitor Clc charges a differential voltage between a data signal supplied to a pixel electrode through the thin film transistor TR and a common voltage Vcom supplied to the common electrode 372 and controls a light-transmissive amount by driving liquid crystals in accordance with the charged voltage. The storage capacitor Cst stably maintains the voltage charged in the liquid crystal capacitor Clc.

The display device 1000 according to further still another aspect of the present disclosure may include at least one of the thin film transistors 100, 200, 300, 400, 500 and 600 shown in FIGS. 1 and 4 to 8.

According to the present disclosure, the following advantageous effects may be obtained.

The thin film transistor according to one aspect of the present disclosure may have a large s-factor.

The thin film transistor according to one aspect of the present disclosure includes an active layer having a defect state on a surface. The thin film transistor including an active layer having a defect state on a surface may have a large s-factor.

According to one aspect of the present disclosure, Cu ions may be disposed on the surface of the active layer, and the active layer may be heat-treated, whereby the thin film transistor including an active layer having a defect state on a surface may be fabricated.

Since the thin film transistor according to one aspect of the present disclosure includes an active layer containing Cu ions disposed on a surface, the thin film transistor may have a large s-factor.

The thin film transistor according to one aspect of the present disclosure may be used as a driving element of the display device, and the display device comprising such a thin film transistor may represent a gray scale, and may have excellent display quality.

It will be apparent to those skilled in the art that the present disclosure described above is not limited by the above-described aspects and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor comprising:
an active layer; and
a gate electrode spaced apart from the active layer and at least partially overlapping with the active layer,
wherein the active layer includes copper that has a concentration gradient along a thickness direction of the active layer.

2. The thin film transistor of claim 1, wherein the copper has a uniform concentration on a surface of the active layer.

3. The thin film transistor of claim 1, wherein the copper has a same concentration at different points with a same depth from a surface of the active layer.

4. The thin film transistor of claim 1, wherein the active layer is disposed on a substrate, and the concentration of the copper is reduced along a direction toward the substrate in the active layer.

5. The thin film transistor of claim 1, wherein the copper includes Cu⁺ and Cu²⁺.

6. The thin film transistor of claim 5, wherein the Cu²⁺ has a higher concentration than Cu⁺ in the active layer.

7. The thin film transistor of claim 1, wherein the copper has a concentration of 0.1 at % to 0.18 at % in the active layer.

8. The thin film transistor of claim 1, wherein the active layer includes an oxide semiconductor material.

9. The thin film transistor of claim 1, wherein the active layer includes:
a first oxide semiconductor layer; and
a second oxide semiconductor layer on the first oxide semiconductor layer.

10. The thin film transistor of claim 9, wherein the active layer further includes a third oxide semiconductor layer on the second oxide semiconductor layer.

11. The thin film transistor of claim 1, wherein the thin film transistor has an s-factor of 0.2 or greater.

12. A thin film transistor comprising:
a substrate;
an oxide semiconductor layer functioning as an active layer; and
a gate electrode overlapping with the active layer without contacting each other,
copper (II) oxide disposed in the oxide semiconductor layer and functioning as an acceptor like trap.

13. The thin film transistor of claim 12, wherein a concentration of copper ions in the oxide semiconductor is in a range of 0.1 at % to 0.18 at %.

14. The thin film transistor of claim 12, wherein the thin film transistor has an s-factor of 0.2 or greater.

15. A fabricating method of a thin film transistor, the fabricating method comprising:
forming an active material layer on a substrate;
forming a copper layer on the active material layer;
forming an active layer and a copper pattern by patterning the active material layer and the copper layer;
removing the copper pattern; and
heat-treating the active layer.

16. The fabricating method of claim 15, wherein copper is present on a surface of the active layer after the copper pattern is removed.

17. The fabricating method of claim 15, wherein the copper pattern has a thickness of 2 nm to 5 nm.

18. The fabricating method of claim 15, wherein the heat-treating is performed at a temperature of 250° C. to 350° C.

19. The fabricating method of claim 15, wherein the forming the active material layer includes:
forming a first oxide semiconductor material layer on the substrate; and
forming a second oxide semiconductor material layer on the first oxide semiconductor material layer.

20. The fabricating method of claim 17, wherein the forming the active material layer further includes forming a third oxide semiconductor material layer on the second oxide semiconductor material layer.

21. A display device comprising:
a display element; and
a pixel driving circuit to drive the display element,
wherein the pixel driving circuit includes a thin film transistor, the thin film transistor comprising:
an active layer; and
a gate electrode spaced apart from the active layer and at least partially overlapping with the active layer,
wherein the active layer includes copper that has a concentration gradient along a thickness direction of the active layer.
